(19) United States
(12) Patent Application Publication
(10) Pub. No.: US 2011/0005585 A1
(43) Pub. Date: Jan. 13, 2011

(54) Laser-Scribing Method to Make a Bifacial Thin Film Solar Cell and the Structure Thereof

(75) Inventors: Feng-Chien Hsieh, Changhua County (TW); Gwo-Sen Lin, Taichung City (TW); Chien-Pang Yang, Taipei City (TW); Bing-Yi Hou, Tainan County (TW)

Correspondence Address: WPAT, PC;INTELLECTUAL PROPERTY ATTORNEYS, 2030 MAIN STREET, SUITE 1300, IRVINE, CA, 92614, US

(73) Assignee: NEXPOWER TECHNOLOGY CORP., Taichung County (TW)

(21) Appl. No.: 12/833,681

(22) Filed: Jul. 9, 2010

(30) Foreign Application Priority Data
Jul. 10, 2009 (TW) 098123419

(51) Int. Cl. H01L 31/0288; H01L 31/02; H01L 31/0256; H01L 31/18

(52) U.S. Cl. 136/255; 136/252; 136/262; 136/260; 438/95; 257/E31.015

(57) ABSTRACT

The present invention discloses a laser-scribing method to make a bifacial thin film solar cell and the structure thereof. The laser-scribing method is to form scribing patterns that penetrate different structural layers during the process of forming various structural layers. After the laser-scribing, the top solar cell unit is attached with the bottom solar cell unit by various combining steps to form a solar cell assembly. The solar cell assembly can receive light from both sides via the absorber layers of both of the top solar cell unit and the bottom solar cell unit. The solar cell assembly has an increased output efficiency and a greater power density and the cost of the manufacturing is therefore reduced.

### BACKGROUND OF THE INVENTION

1. Field of the Invention

The present invention relates to a laser-scribing method to make a a bifacial thin film solar cell and the structure thereof, more particularly to a method to form a dual-side light absorbing solar cell and its structure so as to increase the output efficiency.

2. Description of the Prior Art

A solar cell, or a solar chip or a photovoltaic cell, is a photovoltaic semiconductor device that directly converts the energy of the sunlight into electricity and outputs a current with a voltage by the photoelectric effect. The method of solar powered electrical generation is an environmentally protecting power-generating method. During the process of the solar powered electrical generation, no carbon dioxide and other greenhouse gases are generated, and therefore the environment will not be polluted. The solar cell can be classified as a silicon-based solar cell, a thin film solar, a dye-sensitized solar cell, or an organic/polymer solar cell, according to the categories of the light-absorbing material used in the solar cell.

Please refer to FIG. 1, which is a schematic view of a conventional solar cell. The conventional solar cell 1 comprises a back electrode of molybdenum (Mo) 42, a absorber layer 58, a buffer layer 56, an intrinsic zinc oxide (i-ZnO) layer 54 and a transparent conductive layer 52. The back electrode of molybdenum (Mo) 42, the absorber layer 58, the buffer layer 56, the intrinsic zinc oxide (i-ZnO) layer 54 and the transparent conductive layer 52 are stacked sequentially from bottom to top.

However, the conventional solar cell can only permitted the sunlight from either one side thereof. It limits the output effect of the solar cell. Therefore, a better output effect can only be achieved by increasing the quantity of the solar cells and it results in an increasing cost of manufacturing.

### SUMMARY OF THE INVENTION

In order to overcome the shortcomings of the prior arts mentioned previously, the primary object of the present invention is to provide a laser-scribing method for a solar cell that forms laser-scribing patterns that penetrates through different structural layers during the forming process of the first substrate, the first transparent conductive layer, the first intrinsic zinc oxide (i-ZnO) layer, the buffer layer, the first absorber layer, the first back electrode layer and the first insulating layer.

Another object of the present invention is to provide three methods to combine a top solar cell unit and a bottom solar cell unit to form a solar cell assembly. The first method to combine a top solar cell unit and a bottom solar cell unit to form a solar cell assembly comprises the step of attaching the top solar cell unit with the bottom solar cell. During the process of attaching, the top solar cell unit is aligned with the bottom solar cell unit by the same side, and the negative electrode of the top solar cell is disposed with respecting to the positive electrode of the bottom solar cell unit, and the positive electrode of the top solar cell is disposed with respecting to the negative electrode of the bottom solar cell unit. The second method to combine a top solar cell unit and a bottom solar cell unit to form a solar cell assembly comprises the step of attaching the top solar cell unit with the bottom solar cell. During the process of attaching, the top solar cell unit is aligned with the bottom solar cell unit by the same side, and the positive electrode of the top solar cell is disposed with respecting to the positive electrode of the bottom solar cell unit, and the negative electrode of the top solar cell is disposed with respecting to the negative electrode of the bottom solar cell unit. The third method to combine a top solar cell unit and a bottom solar cell unit to form a solar cell assembly comprises the step of scribing a gap on a portion of the first insulating layer of the bottom solar cell by laser and filling-in the gap with a metal of molybdenum (Mo) and the step of attaching the top solar cell unit with the bottom solar cell. The positive electrode of the bottom solar cell electrically and serially connects with a positive electrode of the bottom solar cell unit.

The combining method of the present invention can combine a top solar cell unit and a bottom solar cell unit to form a solar cell assembly. The solar cell assembly can receive the light from the inner house via the first absorber layer of the bottom solar cell unit and also receive the light from the outer environment via the second absorber layer of the top solar cell unit. The solar cell manufactured by the method provided by the present invention has a better output effect and a greater power density when compared with the conventional solar cell. Therefore the cost of the manufacturing process of the solar cell is reduced.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic view of the conventional solar cell;

FIG. 2A through FIG. 2H depicts the steps of the laser-scribing method of a solar cell according to the first preferred embodiment of the present invention;

FIG. 3A through FIG. 3H depicts the steps of the laser-scribing method of a solar cell according to the second preferred embodiment of the present invention;

FIG. 4 depicts the method to combine a top solar cell unit and a bottom solar cell unit according to the third preferred embodiment of the present invention;

FIG. 5 depicts the method to combine a top solar cell unit and a bottom solar cell unit according to the fourth preferred embodiment of the present invention; and

FIG. 6 depicts the method to combine a top solar cell unit and a bottom solar cell unit according to the fifth preferred embodiment of the present invention.

### DESCRIPTION OF THE PREFERRED EMBODIMENT

A detailed description of the present invention will be given below with reference to preferred embodiments thereof, so that a person skilled in the art can readily understand features and functions of the present invention after reviewing the contents disclosed herein. The present invention can also be implemented by or applied in other embodiments, where changes and modifications can be made to the disclosed details from a viewpoint different from that adopted in this specification without departing from the spirit of the present invention.

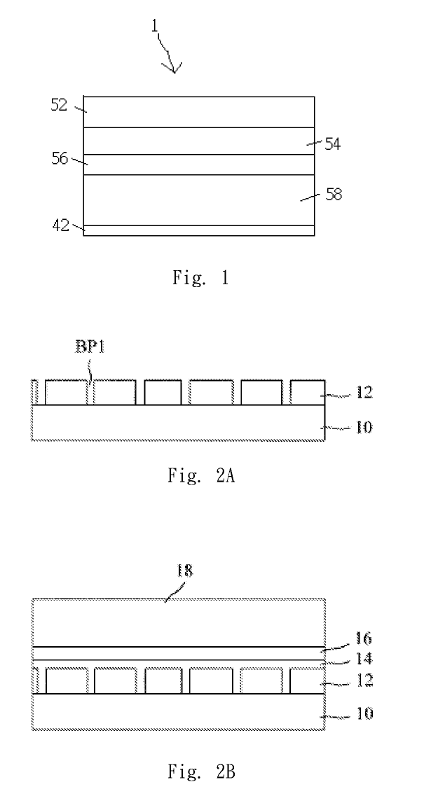

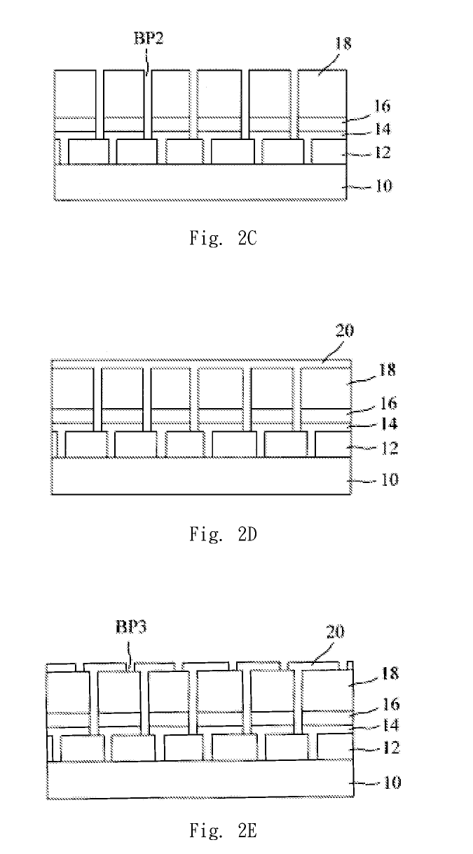

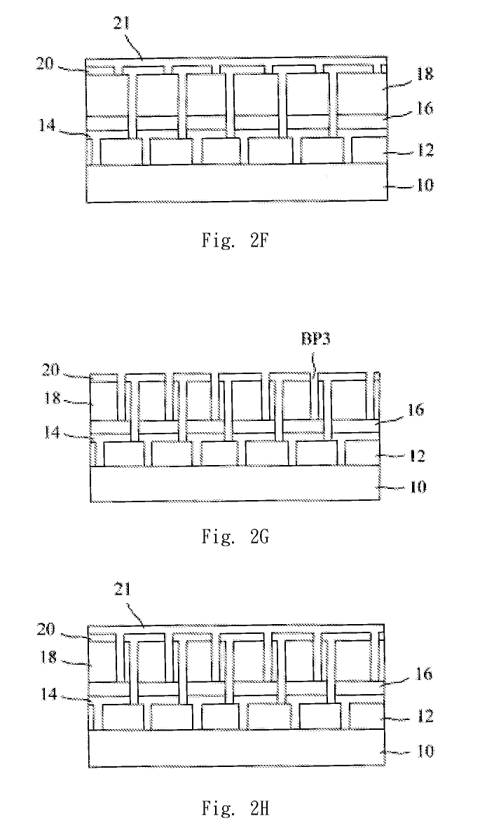

Please refer to FIG. 2A through FIG. 2F. FIGS. 2A through 2F depict the steps of the laser-scribing method for a solar cell according to the first preferred embodiment of the present invention. As shown in FIG. 2A, a first transparent conductive layer 12 is formed on and covers the first substrate 10. A first scribing pattern BP1 is scribed by laser on the first transparent conductive layer 12. As shown in FIG. 2B, a first intrinsic zinc oxide (i-ZnO) layer 14, a first buffer layer 16, and a first absorber layer 18 are sequentially stacked on the first scribing pattern BP1 and the first transparent conductive layer 12.

Later, as shown in FIG. 2C, a second scribing pattern BP2 is scribed by laser and the second scribing pattern BP2 penetrates from the first absorber layer 18 through the first buffer layer 16 and to the first intrinsic zinc oxide layer 14. After scribing the second scribing pattern BP2, as shown in FIG. 2D, a back electrode layer of molybdenum (Mo) 20 is then formed on the second scribing pattern BP2 and the first absorber layer 18.

Moreover, as shown in FIG. 2E, a third scribing pattern BP3 is then scribed on the first back electrode layer of molybdenum (Mo) 20 by laser. A portion of the absorber layer 18 is therefore exposed. Then, as shown in FIG. 2F, an insulating layer 21 is formed on the third scribing pattern BP3 and the first back electrode layer of molybdenum (Mo) 20. Thereby, a bottom solar cell unit is formed.

Alternatively, as shown in FIG. 2G, the third scribing pattern BP3 can also penetrate the first back electrode layer of molybdenum (Mo) 20 and the first absorber layer 18, and therefore a portion of the first buffer layer 16 is exposed. Later, as shown in FIG. 2H, an insulating layer 21 is formed on the third scribing pattern BP3 and the first back electrode layer of molybdenum (Mo) 20. Thereby, a bottom solar cell unit is also formed.

In the first preferred embodiment, the first absorber layer 18 is preferably is made of a Group I-III-VI compound. Such Group I-III-VI compound can be copper indium gallium selenide (CIGS), copper gallium selenide (CGS), copper indium selenide (CIS) or silver indium gallium selenide (AIGS). The first buffer layer 16 preferably comprises a material that can be indium diselenide (InSe2), cadmium sulfide (CdS) or zinc sulfide (ZnS). And the first transparent conductive layer 12 preferably comprises aluminum doped zinc oxide (AZO).

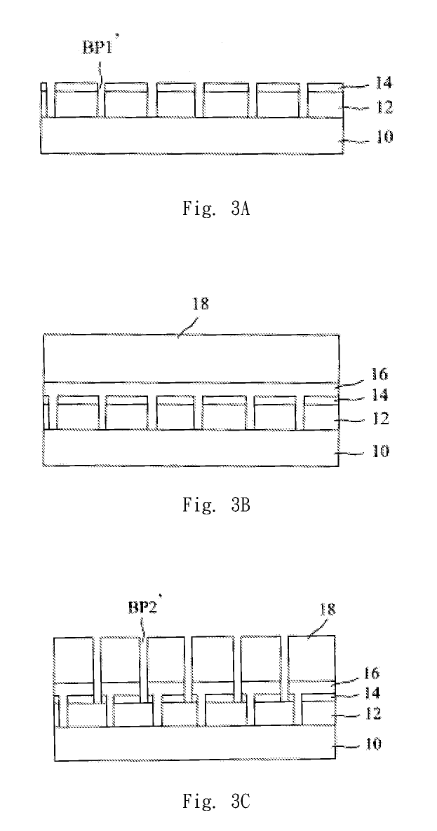

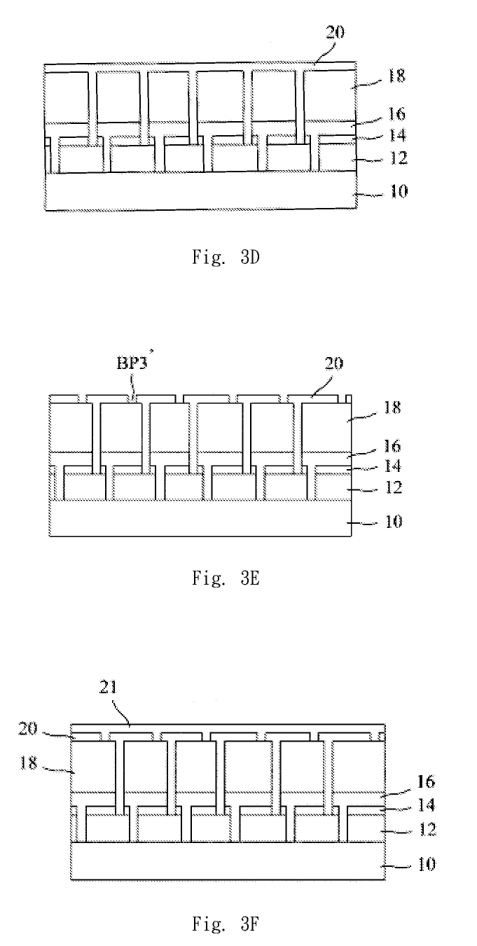

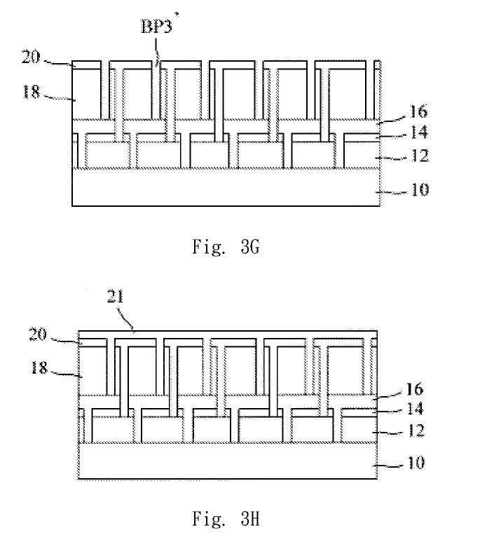

Please refer to FIG. 3A through FIG. 3F. FIGS. 3A through 3F depict the steps of the laser-scribing method for a solar cell according to the second preferred embodiment of the present invention. As shown in FIG. 3A, a first transparent conductive layer 12 and a first intrinsic zinc oxide layer 14 are, from bottom to top, sequentially formed on and covers the first substrate 10. Later, a fourth scribing pattern BP1′ is scribed by laser. The fourth scribing pattern BP1′ penetrates from the first transparent conductive layer 12 to the intrinsic zinc oxide layer 14. As shown in FIG. 3B, a first buffer layer 16 and a first absorber layer 18 are then sequentially formed on the fourth scribing pattern BP1′ and the first intrinsic zinc oxide layer 14.

Later, as shown in FIG. 3C, a fifth scribing pattern BP2′ is scribed by laser and the second scribing pattern BP2 penetrates from the first absorber layer 18 through the first buffer layer 16 to the first intrinsic zinc oxide layer 14. After scribing the fifth scribing pattern BP2′, as shown in FIG. 3D, a back electrode layer of molybdenum (Mo) 20 is then formed on the fifth scribing pattern BP2′ and the first absorber layer 18. Moreover, as shown in FIG. 3E, a sixth scribing pattern BP3′ is then scribed on the back electrode layer of molybdenum (Mo) 20 by laser. The sixth scribing pattern BP3′ penetrates the back electrode layer of molybdenum (Mo) 20 and a portion of the first absorber layer 18 is therefore exposed. Later, as shown in FIG. 3F, an insulating layer 21 is then formed on the sixth scribing pattern BP3′ and the back electrode layer of molybdenum (Mo) 20. Thereby, a bottom solar cell unit is formed.

Alternatively, as shown in FIG. 3G, the sixth scribing pattern BP3′ can also penetrate the first back electrode layer of molybdenum (Mo) 20 and the first absorber layer 18, and therefore a portion of the first buffer layer 16 is exposed. Later, as shown in FIG. 3H, an insulating layer 21 is formed on the sixth scribing pattern BP3′ and the first back electrode layer of molybdenum (Mo) 20. Thereby, a bottom solar cell unit is also formed.

In the second preferred embodiment, the first absorber layer 18 is preferably is made of a Group I-III-VI compound. Such Group I-III-VI compound can be copper indium gallium selenide (CIGS), copper gallium selenide (CGS), copper indium selenide (CIS) or silver indium gallium selenide (AIGS). The first buffer layer 16 preferably comprises a material that can be indium diselenide (InSe2), cadmium sulfide (CdS) or zinc sulfide (ZnS). And the first transparent conductive layer 12 preferably comprises aluminum doped zinc oxide (AZO).

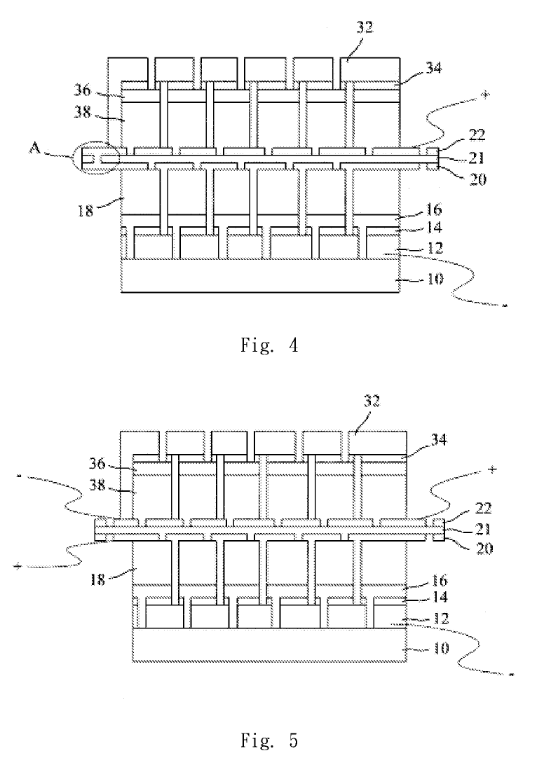

Please refer to FIG. 4 that depicts, according to the third preferred embodiment of the present invention, the method to combine a top solar cell unit and a bottom solar cell unit to form a solar cell assembly. The bottom solar cell unit used here can be made from the method of the first preferred embodiment or the second preferred embodiment to form a solar cell assembly. However, in this preferred embodiment, it is the bottom solar cell unit made from the second preferred embodiment to be used as the example for the following description.

The top solar cell unit comprises sequentially stacked, from bottom to top, a second back electrode layer of molybdenum (Mo) 22, a second absorber layer 38, a second buffer layer 36, a second intrinsic zinc oxide layer 34, and a second transparent conductive layer 32.

The method according to this preferred embodiment of the present invention comprises the step of, as shown in FIG. 4, scribing a gap A on a portion of the first insulating layer 21 of the bottom solar cell by laser, and filling-in the gap A with a metal of molybdenum (Mo) which contacts the first back electrode layer of molybdenum (Mo). Later, the top solar cell unit is then attached with the bottom solar cell to form an integrality. The top solar cell unit is disposed on the bottom solar cell unit, and the negative electrode of the top solar cell electrically and serially connects with the positive electrode of the bottom solar cell unit. The gap A is therefore positioned at the negative electrode of top solar cell unit and at the positive electrode of the bottom solar cell. The metal of molybdenum (Mo) filled in the gap A is functioned to serially and electrically conduct the top solar cell unit and the bottom solar cell unit.

Please refer to FIG. 5 that depicts, according to the fourth preferred embodiment of the present invention, the method to combine a top solar cell unit and a bottom solar cell unit to form a solar cell assembly. The top solar cell unit and the bottom solar cell unit used here are substantially the same as those described in the third preferred embodiment. The method according to this preferred embodiment of the present invention comprises the step of attaching the top solar cell unit with the bottom solar cell to form an integrality. The top solar cell unit is disposed on the bottom solar cell unit. The top solar cell unit is aligned with the bottom solar cell unit by the same side. The positive electrode of the top solar cell is disposed with respecting to the negative electrode of the bottom solar cell unit, and the negative electrode of the top solar cell is disposed with respecting to the positive electrode of the bottom solar cell unit.

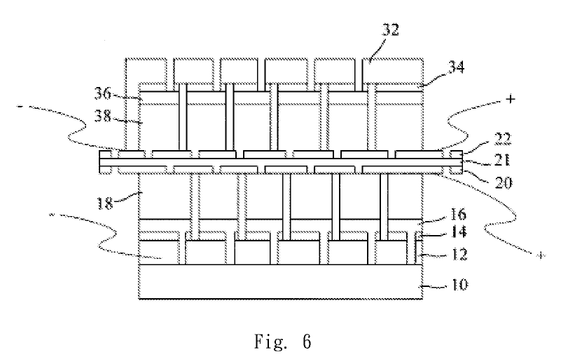

Please refer to FIG. 6 that depicts, according to the fifth preferred embodiment of the present invention, the method to combine a top solar cell unit and a bottom solar cell unit to form a solar cell assembly. Except that, when the top solar cell unit is aligned with the bottom solar cell unit by the same side, the positive electrode of the top solar cell is disposed with respecting to the positive electrode of the bottom solar cell unit and the negative electrode of the top solar cell is disposed with respecting to the negative electrode of the bottom solar cell unit, other elements in this preferred embodiment are substantially the same as those described in the fourth embodiment.

In addition, in the third, fourth and fifth preferred embodiment, the second absorber layer 38 is preferably is made of a Group I-III-VI compound. Such Group I-III-VI compound can be copper indium gallium selenide (CIGS), copper gallium selenide (CGS), copper indium selenide (CIS) or silver indium gallium selenide (AIGS). The second buffer layer 36 preferably comprises a material that can be indium diselenide (InSe2), cadmium sulfide (CdS) or zinc sulfide (ZnS). And the second transparent conductive layer 32 preferably comprises aluminum doped zinc oxide (AZO).

The present invention can also be implemented by or applied in other embodiments, where changes and modifications can be made to the disclosed details from a viewpoint different from that adopted in this specification without departing from the spirit of the present invention.

What is claimed is:

1. A laser-scribing method to make a bifacial thin film solar cell, comprising:
forming a transparent layer on a substrate;
scribing a first scribing pattern on the transparent conductive layer by laser, and then, on the first scribing pattern and the transparent conductive layer, sequentially forming a buffer layer and an absorbing layer;
scribing a second scribing-pattern which penetrates from the absorber layer through the buffer layer by laser, and then forming a back electrode layer of molybdenum (Mo) on the second scribing pattern and the absorber layer;
scribing a third scribing pattern on the back electrode layer of molybdenum (Mo) by laser; and,
forming an insulating layer on the third scribing pattern and the back electrode layer of molybdenum (Mo) whereby to form a bottom unit of the bifacial thin film solar cell.

2. The laser-scribing method to make a bifacial thin film solar cell of claim 1, further comprising a step to form an intrinsic zinc-oxide layer on the transparent layer before the first scribing pattern is scribed.

3. The laser-scribing method to make a bifacial thin film solar cell of claim 1, further comprising a step to form an intrinsic zinc-oxide layer on the transparent layer before the second scribing pattern is scribed.

4. The laser-scribing method to make a bifacial thin film solar cell of claim 1, wherein the absorber layer is made of a Group I-III-VI compound which is selected from the group consisting of copper indium gallium selenide (CIGS), copper gallium selenide (CGS), copper indium selenide (CIS) and silver indium gallium selenide (AIGS).

5. The laser-scribing method to make a bifacial thin film solar cell of claim 1, wherein the buffer layer comprises a material which is selected from the group consisting of indium diselenide (InSe2), cadmium sulfide (CdS) and zinc sulfide (ZnS).

6. The laser-scribing method to make a bifacial thin film solar cell of claim 1, wherein the transparent conductive layer comprises aluminum doped zinc oxide (AZO).

7. The laser-scribing method to make a bifacial thin film solar cell of claim 1, wherein the third scribing pattern penetrates from the back electrode layer of molybdenum through the absorber layer by laser.

8. A laser-scribing method to make a bifacial thin film solar cell, comprising:
forming a first transparent layer on a substrate;
scribing a first scribing pattern on the first transparent conductive layer by laser, and then, on the first scribing pattern and the first transparent conductive layer, sequentially forming a first buffer layer and a first absorbing layer;
scribing a second scribing-pattern which penetrates from the first absorber layer through the first buffer layer by laser, and then forming a first back electrode layer of molybdenum (Mo) on the second scribing pattern and the first absorber layer;
scribing a third scribing pattern on the first back electrode layer of molybdenum (Mo) by laser;
forming an insulating layer on the third scribing pattern and the first back electrode layer of molybdenum (Mo) whereby to form a bottom unit of the bifacial thin film solar cell;
forming a second back electrode layer of molybdenum (Mo) and scribing a fourth scribing pattern on by laser;
forming a second absorber layer and a second buffer layer and than scribing a fifth scribing-pattern by laser; and,
forming a second transparent conductive layer and scribing a sixth scribing pattern on the second transparent conductive layer by laser whereby to form a top unit of the bifacial thin film solar cell.

9. The laser-scribing method to make a bifacial thin film solar cell of claim 8, further comprising a step to form an intrinsic zinc-oxide layer on the first transparent layer before the first scribing pattern is scribed.

10. The laser-scribing method to make a bifacial thin film solar cell of claim 8, further comprising a step to form an intrinsic zinc-oxide layer on the first transparent layer before the second scribing pattern is scribed.

11. The laser-scribing method to make a bifacial thin film solar cell of claim 8, wherein the first and second absorber layer is made of a Group I-III-VI compound which is selected from the group consisting of copper indium gallium selenide (CIGS), copper gallium selenide (CGS), copper indium selenide (CIS) and silver indium gallium selenide (AIGS).

12. The laser-scribing method to make a bifacial thin film solar cell of claim 8, wherein the first and second buffer layer comprises a material which is selected from the group consisting of indium diselenide (InSe2), cadmium sulfide (CdS) and zinc sulfide (ZnS).

13. The laser-scribing method to make a bifacial thin film solar cell of claim 8, wherein the first transparent conductive layer comprises aluminum doped zinc oxide (AZO).

14. The laser-scribing method to make a bifacial thin film solar cell of claim 8, wherein the third scribing pattern penetrates from the first back electrode layer of molybdenum through the first absorber layer by laser.

15. A bifacial thin film solar cell, comprising:
a transparent layer on a substrate;
a first scribing pattern on the transparent conductive layer scribed by laser;
an intrinsic zinc-oxide layer on the transparent layer
a buffer layer on the intrinsic zinc-oxide layer;
an absorbing layer on the buffer layer;
a second scribing-pattern which penetrates from the absorber layer through the buffer layer scribed by laser,
a back electrode layer of molybdenum (Mo) formed on the second scribing pattern and the absorber layer;
a third scribing pattern scribed on the back electrode layer of molybdenum (Mo) by laser;
an insulating layer formed on the third scribing pattern and the back electrode layer of molybdenum (Mo) whereby to form a bottom unit of the bifacial thin film solar cell.

16. The bifacial thin film solar cell of claim 15, wherein the absorber layer is made of a Group I-III-VI compound which is selected from the group consisting of copper indium gallium selenide (CIGS), copper gallium selenide (CGS), copper indium selenide (CIS) and silver indium gallium selenide (AIGS).

17. The bifacial thin film solar cell of claim 15, wherein the buffer layer comprises a material which is selected from the group consisting of indium diselenide (InSe2), cadmium sulfide (CdS) and zinc sulfide (ZnS).

18. The bifacial thin film solar cell of claim 15, wherein the transparent conductive layer comprises aluminum doped zinc oxide (AZO).
